(19) United States
(12) Patent Application Publication
(10) Pub. No.: US 2025/0154649 A1
(43) Pub. Date: May 15, 2025

(54) SILICON NITRIDE FILM FORMATION METHOD AND PLASMA PROCESSING APPARATUS

(71) Applicant: Tokyo Electron Limited, Tokyo (JP)

(72) Inventors: Kenichi KOTE, Yamanashi (JP); Takafumi NOGAMI, Yamanashi (JP)

(21) Appl. No.: 19/024,424

(22) Filed: Jan. 16, 2025

Related U.S. Application Data
(63) Continuation of application No. PCT/JP2023/025190, filed on Jul. 6, 2023.

(30) Foreign Application Priority Data
Aug. 2, 2022 (JP) 2022-123217

(51) Int. Cl. C23C 16/34; C23C 16/511; H01J 37/32; H01L 21/02

(52) U.S. Cl. CPC C23C 16/345; C23C 16/511; H01J 37/32449; H01L 21/0217; H01L 21/02274; H01J 37/32192; H01J 37/32862; H01J 2237/332

(57) ABSTRACT

There is provided an SiN film formation method that includes: a) loading a substrate into a processing chamber; b) supplying a nitrogen-containing gas to the processing chamber; c) after b), applying electromagnetic power to generate plasma of the nitrogen-containing gas in the processing chamber; and d) after c), supplying a silicon-containing raw material gas to the processing chamber, and allowing the silicon-containing raw material gas to react with the plasma of the nitrogen-containing gas, thereby forming an SiN film on the substrate.

### CROSS-REFERENCE TO RELATED APPLICATIONS

This application is a continuation application of International Application No. PCT/JP2023/025190 filed on Jul. 6, 2023, which is based on and claims priority to Japanese Patent Application No. 2022-123217 filed on Aug. 2, 2022, the contents of which are incorporated herein by reference in their entirety.

### BACKGROUND

### 1. Field of the Invention

The present disclosure relates to silicon nitride (SiN) film formation methods and plasma processing apparatuses.

### 2. Description of the Related Art

For production of semiconductor devices, good film quality and productivity are desired. In single wafer processing, an interior of a chamber is precoated, after the precoating, a predetermined number of substrates are subjected to film formation processing, and then dry cleaning is performed. In order to deposit a high quality film, it is important to reduce the number of particles. If a cleaning cycle is shortened in order to inhibit generation of particles, productivity is lowered.

For example, International Publication No. 2008/035678 describes a method for SiN film formation method and plasma cleaning. In the disclosed method, at the time of formation of an SiN film, an silicon (Si)-containing gas and a nitrogen-containing gas are introduced into a processing chamber at the predetermined flow rates, followed by introducing microwave power, thereby forming the Si-containing gas and the nitrogen-containing gas into plasma, and a substrate is exposed to the plasma.

For example, Japanese Unexamined Patent Application Publication No. 2007-048982 describes that an Ar gas is supplied to a processing chamber, followed by supplying microwave power to the processing chamber to induce plasma ignition of the Ar gas with the microwave power, and then an SiH₄ gas and an NH₃ gas are supplied to deposit an SiN film.

For example, Japanese Unexamined Patent Application Publication No. 2014-060378 describes that, if microwave power is applied with a slight delay after supplying an Ar gas, an N₂ gas, a H₂ gas, and an SiH₄ gas, supply of the gases and supply of the microwave power are stabilized when a predetermined time elapses after the start of the supply.

For example, Japanese Unexamined Patent Application Publication No. 2017-226894 describes that a processing target is placed in a chamber, plasma is generated while supplying a film forming gas and a helium gas to the chamber, and the plasma causes excitation of the film forming gas, thereby depositing a predetermined film on the processing target.

### SUMMARY

According to one aspect of the present disclosure, there is provided an SiN film formation method that includes: a) loading a substrate into a processing chamber; b) supplying a nitrogen-containing gas to the processing chamber; c) after b), applying electromagnetic power to generate plasma of the nitrogen-containing gas in the processing chamber; and d) after c), supplying a silicon-containing raw material gas to the processing chamber, and allowing the silicon-containing raw material gas to react with the plasma of the nitrogen-containing gas, thereby forming an SiN film on the substrate.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic view illustrating a configuration example of a plasma processing apparatus according to one embodiment;

FIG. 2 is a flowchart illustrating an example of a process of precoating, film formation, and cleaning according to one embodiment;

FIG. 3A is a timing diagram illustrating an example of a film formation process according to a referential example;

FIG. 3B is a timing diagram illustrating an example of a film formation process according to one embodiment;

FIG. 4 is a flowchart illustrating an example of a film formation process according to one embodiment;

FIG. 5A is a graph depicting an example of an effect (particle reduction) of the film formation process according to one embodiment;

FIG. 5B is a graph depicting the example of the effect (particle reduction) of the film formation process according to one embodiment;

FIG. 6 is a graph depicting an example of an effect (WER) of the film formation process according to one embodiment; and

FIG. 7 is a graph depicting an example of an effect of the film formation process according to one embodiment.

### DETAILED DESCRIPTION

Hereinafter, non-limiting embodiments of the present disclosure will be described with reference to the attached drawings. Throughout the attached drawings, the same or corresponding members or parts are designated by the same or corresponding reference symbols, and redundant description thereof will be omitted.

### Plasma Processing Apparatus

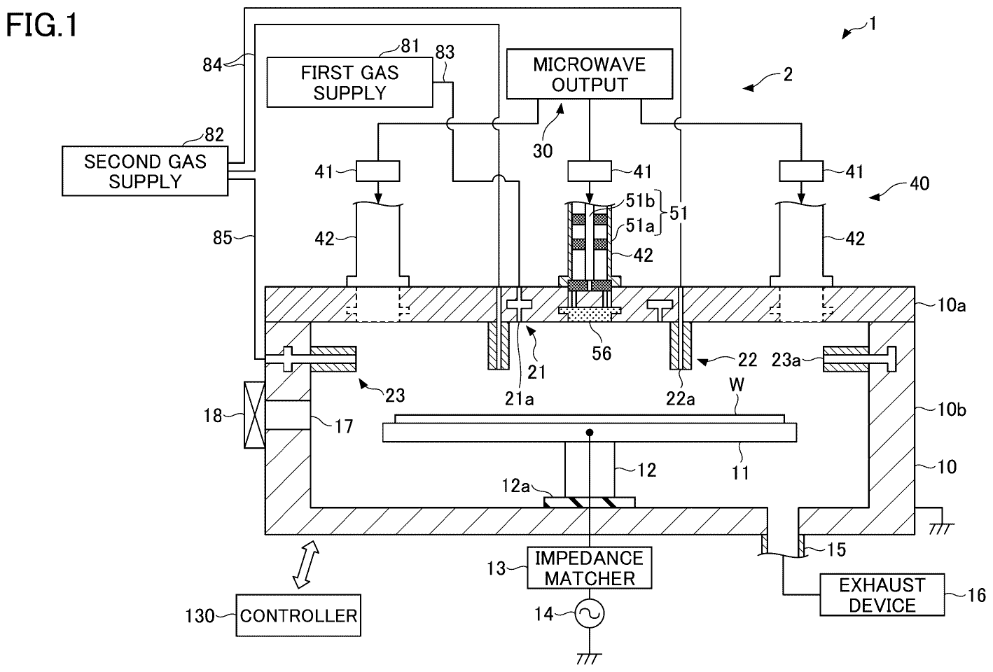

A configuration example of a plasma processing apparatus that executes a film formation method according to the present embodiment will be described with reference to FIG. 1. FIG. 1 is a view illustrating a configuration example of a plasma processing apparatus 1 including a microwave plasma source according to one embodiment.

The plasma processing apparatus 1 includes a processing chamber 10 and a plasma source 2. The processing chamber 10 is airtightly formed of a metal material, such as aluminum or the like, and has substantially a cylindrical shape. The processing chamber 10 is grounded. The plasma source 2 supplies microwaves to the processing chamber 10 to form surface wave plasma. A ceiling wall 10a of the processing chamber 10 is configured such that dielectric members (may be referred to as dielectric windows 56 hereinafter) of microwave radiation sources 42 are fitted into a main body formed of the metal. Thus, the plasma source 2 is configured to supply microwaves into the processing chamber 10 through the dielectric windows 56 in the ceiling wall 10a.

The plasma processing apparatus 1 includes a controller 130. The controller 130 is, for example, a computer, and includes a processor and a program storage (not illustrated). One or more programs for controlling processing of a substrate W, such as a semiconductor wafer, performed in the plasma processing apparatus 1 are stored in the program storage. Note that the one or more programs may be recorded on a computer-readable storage medium, such as a computer-readable hard disk (HD), a flexible disk (FD), a compact disk (CD), a magneto-optical disk (MO), a memory card, or the like, or may be installed from the storage medium into the controller 130.

In the processing chamber 10, a stage 11 that horizontally supports a substrate W is disposed. The stage 11 is supported by a cylindrical support member 12 that is vertically disposed at a center of the bottom of the processing chamber 10 via an insulating member 12a. A material constituting the stage 11 and the support member 12 may include, for example, a metal, such as aluminum whose surface is subjected to the alumite treatment (anodizing treatment), or an insulating material (a ceramic, etc.) including an electrode for high-frequency waves inside the insulating material.

Although they are not illustrated, the stage 11 may include a temperature regulator, a gas channel for supplying a gas for transmitting heat to a back surface of a substrate W, and lifting pins that lift up and lower down to transport a substrate W. Moreover, an electrostatic chuck for electrostatically holding a substrate W may be provided to the stage 11.

In addition, an RF bias power source 14 is electrically connected to the stage 11 via an impedance matcher 13. Since the RF bias power source 14 supplies RF bias power to the stage 11, ions in plasma are drawn toward a substrate W, thereby improving a film quality and in-plane uniformity.

An exhaust pipe 15 is coupled to the bottom side of the processing chamber 10, and an exhaust device 16 including a vacuum pump is coupled to the exhaust pipe 15. By operating the exhaust device 16, the atmosphere in the processing chamber 10 can be exhausted, and the internal pressure of the processing chamber 10 can be reduced and adjusted to a set pressure. In addition, a loading port 17 through which a substrate W is transported in and out, and a gate valve 18 for opening and closing the loading port 17 are provided to a side wall 10b of the processing chamber 10.

The plasma processing apparatus 1 also includes a first gas shower 21 for discharging a predetermined gas from the ceiling wall 10a of the processing chamber 10 to the processing chamber 10. Moreover, the plasma processing apparatus 1 includes a second gas shower 22 that includes a nozzle vertically extending downward from the ceiling wall 10a of the processing chamber 10 and introduces a gas at a position between the ceiling wall 10a and the stage 11. Further, the plasma processing apparatus 1 includes a third gas shower 23 that includes a nozzle projecting inward from the side wall 10b of the processing chamber 10, and introduces a gas at a position between the side wall 10b and the stage 11 and at an outer position relative to the second gas shower 22. For convenience, the first gas shower 21 and the second gas shower 22 are illustrated as being disposed at positions that are shifted from each other in a radial direction in FIG. 1, but the first gas shower 21 and the second gas shower 22 are alternately disposed on a same circle.

The first gas shower 21 is disposed in the ceiling wall 10a of the processing chamber 10, and includes a gas supply hole 21a for supplying gas from the ceiling wall 10a. A gas transported from a first gas supply 81 through a gas line 83 is supplied from the gas supply hole 21a at a first position.

The second gas shower 22 includes a nozzle vertically extending downward from the ceiling wall 10a of the processing chamber 10, and a gas supply hole 22a for supplying a gas from an edge of the nozzle. A gas transported from a second gas supply 82 through a gas line 84 is supplied from the gas supply hole 22a at a second position that is the nozzle edge position. The second position is lower than the first position. The gas supply hole 22a is one example of the first gas supply hole configured to supply a gas from the ceiling wall 10a.

The third gas shower 23 is disposed in the side wall 10b of the processing chamber 10. The third gas shower 23 includes a nozzle projecting inward from the side wall 10b, and a gas supply hole 23a for supplying a gas from the edge of the nozzle. A gas transported from the second gas supply 82 through a gas line 85 is supplied from the gas supply hole 23a at a third position that is a nozzle edge position. The third position is disposed on the outer peripheral side compared with the first position and the second position. The gas supply hole 23a is one example of the second gas supply hole configured to supply a gas from the side wall 10b.

A raw material gas (film forming gas) is supplied from the second gas shower 22 and the third gas shower 23. In the case where an SiN film is formed, for example, a silane (SiH₄) gas, which is one example of the raw material gas, is supplied from the second gas shower 22 and the third gas shower 23. Alternatively, the raw material gas may be supplied, for example, from the second gas shower 22, the third gas shower 23, and both.

A reaction gas may be supplied from the first gas shower 21, the second gas shower 22, the third gas shower 23, or any combination of the foregoing. In the case where an SiN film is formed, for example, a nitrogen-containing gas, which is one example of the reaction gas, may be supplied from the first gas shower 21, the second gas shower 22, the third gas shower 23, or any combination of the foregoing. The nitrogen-containing gas may be an ammonia (NH₃) gas, a nitrogen (N₂) gas, a gas mixture of a nitrogen (N₂) gas and a hydrogen (H₂) gas, or a gas mixture including any combination of the preceding gasses.

The plasma source 2 includes a microwave output 30 that outputs microwaves while distributing the microwaves into multiple paths, and a microwave transmitter 40 that transmits microwaves output from the microwave output 30. The plasma source 2 is one example of the electromagnetic wave source that applies electromagnetic wave power.

The microwave output 30 includes a microwave power source, a microwave oscillator, an amplifier, and a power splitter. The microwave power source supplies power to the microwave oscillator. The microwave oscillator oscillates and generates microwaves of predetermined frequencies (e.g., 860 MHz) by the phase-locked loop (PLL). The amplifier amplifies the oscillated microwaves. The power splitter splits the microwaves amplified by the amplifier, while matching the impedance between the input side and the output side so that the loss of the microwaves is minimized. As the frequency of the microwaves, in addition to 860 MHz, various frequencies in the range of 700 MHz to 3 GHz, such as 915 MHz and the like, can be used.

The microwave transmitter 40 includes multiple amplifiers 41 and multiple microwave radiation sources 42 provided corresponding to the amplifiers 41. For example, one microwave radiation source 42 is disposed at the center of the ceiling wall 10a, and six microwave radiation sources 42 are disposed at equal intervals on the circumference around the microwave radiation source 42 disposed at the center of the ceiling wall 10a, as a center of the circumference. Thus, seven microwave radiation sources 42 are disposed in total. In the present example, the microwave radiation sources 42 are disposed in a manner such that the distance between the microwave radiation source 42 at the center and each of the microwave radiation sources 42 at the circumference is equal to the distance between the adjacent microwave radiation sources 42 disposed at the circumference.

Each amplifier 41 guides the microwaves split by the power splitter to a corresponding microwave radiation source 42. The microwave radiation source 42 includes a coaxial pipe 51. The coaxial pipe 51 includes a coaxial microwave transmitting path that is created by a cylindrical outer conductor 51a and a rod-shaped inner conductor 51b that is disposed at a center of the cylindrical outer conductor 51a. Each microwave radiation source 42 includes a power supply antenna (not illustrated) that supplies the microwaves amplified by the amplifier 41 to the coaxial pipe 51. In addition, each microwave radiation source 42 includes a tuner that matches the load impedance with characteristic impedance of the microwave power source, and an antenna that radiates microwaves from the coaxial pipe into the processing chamber 10.

Each antenna is disposed at the bottom end of the coaxial pipe 51, and is fitted into a metal portion of the ceiling wall 10a of the processing chamber 10. The antenna includes a dielectric window 56, and the microwaves transmitted through the dielectric window 56 generate surface wave plasma immediately below the dielectric window 56 inside the processing chamber 10.

One microwave radiation source 42 (dielectric window 56) is disposed at the center of the ceiling, and six microwave radiation sources 42 are disposed at the circumference. Each of the microwave radiation sources 42 (dielectric windows 56) can independently control the microwave power supplied from the corresponding microwave radiation source 42. The microwave power supplied from the microwave radiation source 42 (dielectric window 56) at the circumference may be equal to or higher than the microwave power supplied from the microwave radiation source 42 at the center.

The film formation method of the present embodiment can be executed by the plasma processing apparatus, in which microwave power is supplied from the microwave radiation sources 42 disposed in the ceiling wall of the processing chamber 10. However, the film formation method of the present embodiment is not limited to the configuration of the plasma processing apparatus 1 illustrated in FIG. 1, and may be executed by a plasma chemical vapor deposition (CVD) device or a plasma atomic layer deposition (ALD) device.

### Precoating, Film Formation, and Cleaning

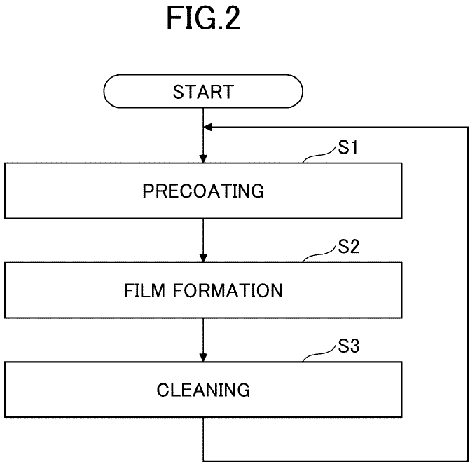

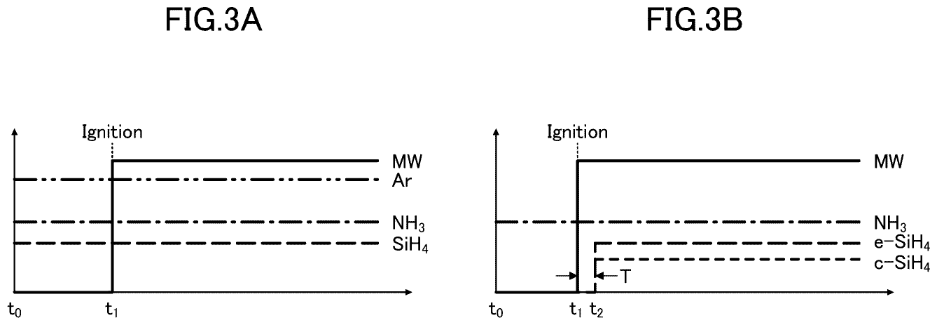

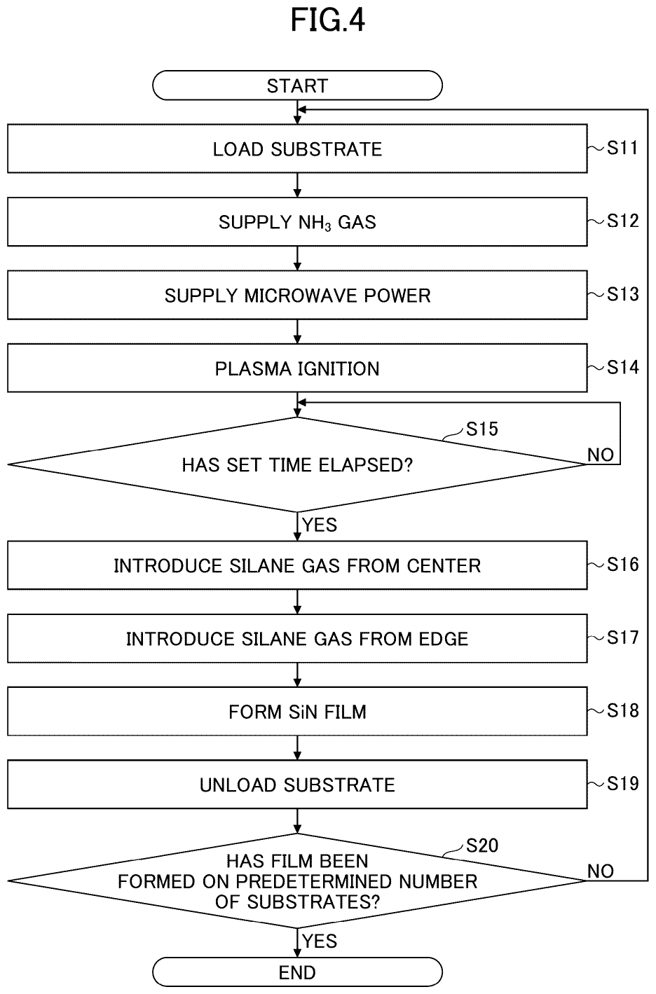

Next, processing of precoating, film formation, and cleaning according to one embodiment will be described with reference to FIGS. 2 to 4. FIG. 2 is a flowchart illustrating an example of processing of precoating, film formation, and cleaning according to one embodiment. FIG. 3A is a timing diagram illustrating an example of a film formation process according to a referential example; and FIG. 3B is a timing diagram illustrating an example of a film formation process according to one embodiment. FIG. 4 is a flowchart illustrating an example of a film formation process according to one embodiment.

The process illustrated in FIGS. 2 to 4 is executed, for example, by the plasma processing apparatus 1 under the control of the controller 130. In FIG. 2, the controller 130 executes precoating that forms a protective film in a processing chamber 10 of the plasma processing apparatus 1 at step S1. The precoating includes formation of a protective film on an interior of a processing chamber 10 of a brand-new plasma processing apparatus 1, or formation of a protective film on an interior of the processing chamber 10 of the plasma processing apparatus 1 after the below-described cleaning.

The protective film may be the same kind of the film or a different kind of the film as a film formed in the subsequent film formation process. In the case where a silicon nitride (SiN film) is formed in the film formation process of step S2, for example, the same SiN film may be formed as a protective film on wall surfaces or the like of the processing chamber 10 in the precoating of step S1. When an SiC film, an SiO film, an SiON film or the like is formed in the film formation process of step S2, for example, a silicon nitride film may be formed.

Next, the controller 130 executes film formation in the processing chamber 10 of the plasma processing apparatus 1 at step S2. The film formation will be described later (see FIGS. 3A, 3B, and 4).

In the film formation, a set number of substrates, for example, twenty five to fifty substrates, are processed. Then, the controller 130 executes dry cleaning that cleans the interior of the processing chamber 10 of the plasma processing apparatus 1 at step S3. During the cleaning, a processing gas including a fluorine-containing gas is supplied to the processing chamber 10, and microwave power is applied from the multiple microwave radiation sources 42. Thus, plasma of the processing gas is generated in the processing chamber 10, and the interior of the processing chamber 10 is exposed to the plasma of the processing gas, thereby cleaning the interior of the processing chamber 10. Examples of the fluorine-containing gas include an NF₃ gas. Moreover, examples of the processing gas including the fluorine-containing gas include a gas mixture including an NF₃ gas and a noble gas (inert gas).

A set temperature of the stage 11 on which a substrate is placed during the film formation of step 2 and a set temperature of the stage 11 during the cleaning of step S3 are the same temperature. For example, the set temperature is 450° C. or lower. If the stage 11 is regulated to have different set temperatures during the film formation and during the cleaning, it takes a long time to regulate the temperature, which may lower throughput. Since the set temperature is the same during the film formation and during the cleaning in the present embodiment, speedy temperature regulation is achieved and throughput can be improved.

After the cleaning of step S3, the process is returned to step S1, an SiN film is again formed as a protective film on the interior of the processing chamber 10, which has been cleaned, and film formation for forming an SiN film on a subsequent substrate is executed at step S2.

### Film Formation

The film formation of step S2 will be described with reference to FIGS. 3A to 5B. FIG. 3A depicts a film formation process of a referential example, and FIG. 3B depicts a film formation process of the present embodiment. In the film formation of the referential example, an argon (Ar) gas functioning as an ignition gas is supplied, but an argon gas is not supplied in the film formation of the present embodiment.

More specifically, in the film formation of the referential example of FIG. 3A, supply of an argon (Ar) gas, an ammonia (NH₃) gas, and a silane (SiH₄) gas is simultaneously started at the time t₀ according to the procedure set in the recipe. While supplying the above gases, microwave (MW) power is applied at the time t₁. The argon gas mainly functions to stabilize ignition and discharge. The argon gas ignites plasma. The silane gas is a raw material gas, and the ammonia gas is a reaction gas. The silane gas and the ammonia gas are used to form an SiN film.

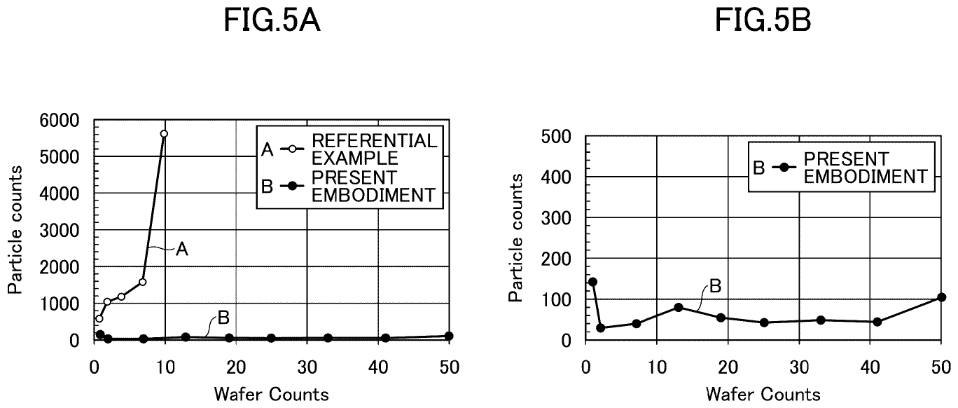

However, in the film formation of the referential example of FIG. 3A, the number of particles generated during the film formation is large. In FIG. 5A, the horizontal axis represents the number of wafers (substrates) processed, and the vertical axis represents the number of particles generated. As depicted by A representing the particle counts of the referential example in FIG. 5A, the number of particles generated during the processing of the first substrate in the film formation of the referential example of FIG. 3A is approximately 500. Then, the number of particles generated during the processing of the second substrate increases to approximately 1,000 or greater, and the number of the particles during the processing of the tenth substrate notably increases to approximately 5,500.

When the argon gas is supplied, a plasma electron density (Nₑ) and plasma electron temperature (Tₑ) become high compared with the case when another gas is supplied. It is considered that the precoated SiN film or the formed SiN film are sputtered by the argon gas to damage the SiN film, thereby notably increasing the number of particles. Thus, cleaning and precoating need to be performed every time a film is formed on one substrate, which lowers productivity.

For production of semiconductor devices, in addition to improvement of productivity, improvement of a film quality having desired etching resistance (hydrofluoric acid resistance) is desired in formation of an SiN film. However, there is a trade-off between a good film quality and high productivity.

For example, when a temperature of the stage 11 during film formation is set to 550° C. and gases and microwaves are supplied according to the procedure illustrated in FIG. 3A to form a film in order to form an SiN film having a good film quality with etching resistance, an SiN film having a good film quality is obtained. In the case where subsequent cleaning is performed at 550° C. that is the same temperature as the temperature in the film formation, however, the wall surfaces of the processing chamber 10 are damaged, which shortens the maintenance cycle, and lowers productivity. Thus, it is important to adjust the temperature of the stage 11 to 550° C. during film formation, and reduce the temperature of the stage 11 to 450° C. during cleaning. In this case, the set temperature during film formation is different from the set temperature during cleaning, and therefore it takes time to adjust the temperature of the stage 11, which lowers productivity.

In contrast, in the present embodiment, there is provided an SiN film formation method which can form an SiN film having excellent etching resistance at high productivity. In the present embodiment, the temperature of the stage 11 during film formation is set to 450° C. or lower and film formation is performed according to the procedure illustrated in FIG. 3B, followed by performing cleaning with the temperature of the stage 11 being set to 450° C. or lower that is the same temperature as the temperature of the stage 11 during the film formation. In this case, the set temperature during film formation is the same temperature as the set temperature during cleaning, and therefore it does not take time to adjust the temperature of the stage 11. Moreover, in order to form an SiN film of a good film quality even when film formation is performed by setting the temperature of the stage 11 to 450° C. or lower, an Ar gas is not supplied (not used) as an ignition gas during film formation.

In the film formation of the present embodiment of FIG. 3B, supply of an ammonia (NH₃) gas is started at the time t₀ according to the procedure set in the recipe. While supplying the ammonia gas, microwave (MW) power is applied at the time t₁. The ammonia gas ignites plasma. After a predetermined time T elapses from the time t₁, a silane (SiH₄) gas is supplied. Thus, an SiN film is formed.

The predetermined time T from the time t₁ to the time t₂ is the duration of a process of stabilizing plasma, which is, for example, from 1 second to 5 seconds. In the case where plasma ignition is performed by microwaves, after the ignition, plasma becomes unstable during a short period of time until impedance is matched and microwaves are stabilized. During the above period, particles are generated if the partial pressure of the silane gas is high. In the present embodiment, an argon gas is not used. Therefore, the partial pressure of the silane gas relative to the entire gas is high compared with the referential example in which the argon gas is used. Thus, the number of particles would be likely to increase.

Accordingly, in the present embodiment, the ammonia gas is supplied at the time t₀, and the supplied ammonia gas is used as an ignition gas. When the predetermined time T elapses after the ignition of the plasma by supply of microwaves, a silane gas is supplied, and the ammonia gas is allowed to act as a reaction gas against the silane gas that is a film forming gas, thereby forming an SiN film. Thus, instability of microwaves can be resolved, and the number of particles can be reduced. Moreover, an SiN film having desired etching resistance (hydrofluoric acid resistance) can be formed.

According to the SiN film formation method of the present embodiment, as depicted by B representing the particle counts of the present embodiment in FIG. 5A, the number of particles is significantly reduced. FIG. 5B is an enlarged view of B representing the particle counts of FIG. 5A. As depicted in FIGS. 5A and 5B, even when an SiN film was formed on fifty substrates without cleaning between successive film formation processes, the number of particles generated during film formation of each substrate was approximately 100 or less.

As described above, according to the SiN film formation method of the present embodiment, an argon gas is not used, and therefore the interior of the processing chamber 10 is unlikely to be damaged. As a result, after performing precoating once, twenty-five to fifty substrates can be processed without performing cleaning. Therefore, the cleaning cycle can be extended, which increases throughput and improves productivity. Since the set temperature during film formation and the set temperature during cleaning are the same in the present embodiment, it does not take time to adjust the temperature of the stage 11. Moreover, even when film formation is performed by setting the temperature of the stage 11 to 450° C. or lower, an excellent SiN film can be obtained. As described above, according to the SiN film formation method of the present embodiment, an SiN film having excellent etching resistance can be formed at high productivity.

### EXAMPLES

An example of a film formation process (SiN film formation process) according to one embodiment will be described with reference to FIG. 4. In the example of the film formation process according to one embodiment illustrated in FIG. 4, supply of a silane gas from an edge and a center of a processing chamber 10 is described as an example. The silane gas supplied from the edge of the processing chamber 10 is the silane gas supplied from the third gas shower 23 of the side wall 10b of the processing chamber 10. The silane gas supplied from the center of the processing chamber 10 is the silane gas supplied from the second gas shower 22 of the ceiling wall 10a of the processing chamber 10.

When the present process is started, in step S11, the controller 130 performs control of loading a substrate into a processing chamber 10. Next, in step S12, the controller 130 performs control of supplying an ammonia gas to the processing chamber 10.

After the supply of the ammonia gas, in step S13, the controller 130 performs control of applying power of microwaves, which are one example of electromagnetic waves. Corresponding to the application of the microwave power, in step S14, the controller 130 performs control of igniting plasma of the ammonia gas, thereby generating plasma of the ammonia gas in the processing chamber 10.

Next, in step S15, the controller 130 performs control of determining whether or not a predetermined time T elapses. The controller 130 performs control of waiting until the predetermined time T elapses, and when it is determined that the predetermined time T elapses, the process proceeds to step S16. In step S16, the controller 130 performs control of supplying a silane gas from the second gas shower 22 (from the center) to the processing chamber 10.

Next, in step S17, the controller 130 performs control of supplying a silane gas from the third gas shower 23 (from the edge) to the processing chamber 10. In step S18, the silane gas is allowed to react with the plasma of the ammonia gas, thereby forming an SiN film on the substrate.

Note that step S16 and step S17 may be performed simultaneously, or step S17 may be performed before step S16.

In step S16 and step S17, a ratio of a flow rate of the silane gas supplied from the second gas shower 22 (gas supply hole 22a) to a flow rate of the silane gas supplied from the third gas shower 23 (gas supply hole 23a) is in the range of 1:1 to 1:5.

In the example of FIG. 3B, the flow rate of the silane gas (e-SiH₄) supplied from the edge is set to be greater than the flow rate of the silane gas (c-SiH₄) supplied from the center, and the silane gas (e-SiH₄) and the silane gas (c-SiH₄) are supplied simultaneously. By controlling the flow rates as described above, partial pressure of the silane gas above the SiN film can be homogeneously controlled so that in-plane thickness distribution of the SiN film can be made uniform.

Next, in step S19, the processed substrate is unloaded.

Next, in step S20, the controller 130 performs control of determining whether or not film formation is performed on a predetermined number of substrates. The predetermined number may be set in the range of 25 to 50 as presented in the particle reduction effect of the present embodiment in FIG. 5B.

In step S20, when the controller 130 determines that film formation is not continuously performed on the predetermined number of substrates, the controller 130 performs control of returning the process back to step S11, loading a subsequent unprocessed substrate, and executing a process of steps S11 to S19 on the loaded unprocessed substrate.

In step S20, when the controller 130 determines that film formation is continuously performed on the predetermined number of substrates, the present process is ended.

According to the SiN film formation method of the present embodiment, an SiN film having desired etching resistance can be formed using an ammonia gas and a silane gas, without using an argon gas. In addition, the cleaning cycle can be extended, and throughput can be increased while maintaining a quality of the SiN film, thereby improving productivity.

In the case of the referential example using an argon gas, the internal pressure of the processing chamber 10 is adjusted to approximately 10 Pa, and plasma is ignited. In contrast, in the SiN film formation method of the present embodiment, the internal pressure of the processing chamber 10 can be set higher, and may be controlled to be greater than 10 Pa and 20 Pa or lower. Thus, plasma can be ignited more stably.

### Film Formation Temperature

In the present embodiment, the set temperature of the stage 11 (film formation temperature) during the film formation (s2) and the set temperature of the stage 11 during the cleaning (s3) in FIG. 2 are controlled to be the same temperature, which is 450° C. or lower. Even at such a low temperature, an SiN film having a quality comparable with a quality of an SiN film formed by adjusting the set temperature of the stage 11 to 550° C. can be formed.

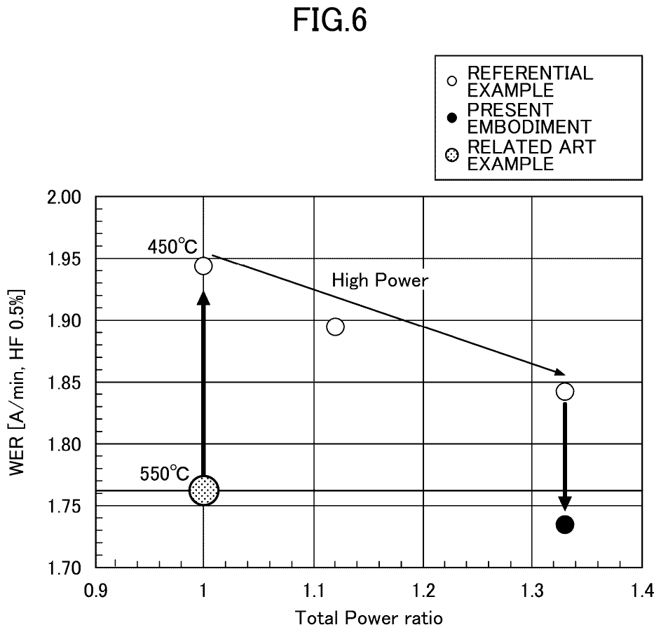

The reduction in the film formation temperature and the maintenance of the film quality will be described with reference to FIG. 6. FIG. 6 is a graph depicting an example of an effect (WER) of the temperature regulation and film formation according to one embodiment. In FIG. 6, the horizontal axis represents a total power ratio of the microwaves applied from seven microwave radiation sources 42, and the vertical axis represents a wet etch rate (WER). The WER of the vertical axis represents an etched amount per minute (Å/min) when the SiN film is immersed in a solution in which hydrofluoric acid is diluted to a concentration of 0.5%.

The total power ratio of the horizontal axis represents a ratio of the total power of microwaves relative to a total power of microwaves applied from seven microwave radiation sources 42 when the set temperature is set at 550° C. in the film formation and cleaning in the related art example or set at 450° C. in the film formation and cleaning in the referential example, among the processing conditions of the referential example of the SiN film formation method before power is increased and the processing conditions of the related art example of the SiN film formation method. The total power ratio is calculated by determining the total power of the referential example or related art example as 1.

Specifically, the processing conditions of the referential example before the power is increased and the processing conditions of the related art example are different from each other only in that the set temperature of the stage 11 in the film formation and cleaning is 450° C. in the referential example and the set temperature of the stage 11 in the film formation and cleaning is 550° C. in the related art example.

The SiN film formed under the conditions of the referential example had a high WER compared with the SiN film formed under the conditions of the related art example, and therefore had low etching resistance. It is considered that the increase in the WER is caused because the set temperature of the stage 11 is reduced to 450° C. in the referential example.

On the other hand, when the total power of microwaves of the referential example was increased (high power) from 1 to the power in the range of 1.3 times to 1.4 times, while maintaining the set temperature of the stage 11 low, i.e., 450° C., the WER of the SiN film was lowered as indicated by the diagonal arrow of FIG. 6. Specifically, the SiN film became less likely to be readily etched, and etching resistance was improved. However, the WER could not be reduced to the level of the WER of the SiN film formed under the conditions of the related art example, i.e., 1.76.

Under the processing conditions of the present embodiment, an argon gas was not used, an ammonia gas functioned as an ignition gas, and an SiN film was formed according to the procedure illustrated in FIG. 3B, while adjusting the set temperature of the stage 11 to 450° C. As a result, WER of the SiN film of the present embodiment could be reduced to the same level as or lower than WER of the SiN film formed under the processing conditions of the related art example. As described above, according to the low temperature process of the present embodiment, in which the temperature of the stage 11 was adjusted to 450° C., the SiN film having a same etching resistance as or superior etching resistance to the etching resistance of the SiN film of the related art example formed by setting the set temperature of the stage 11 to 550° C. could be formed.

### Effects

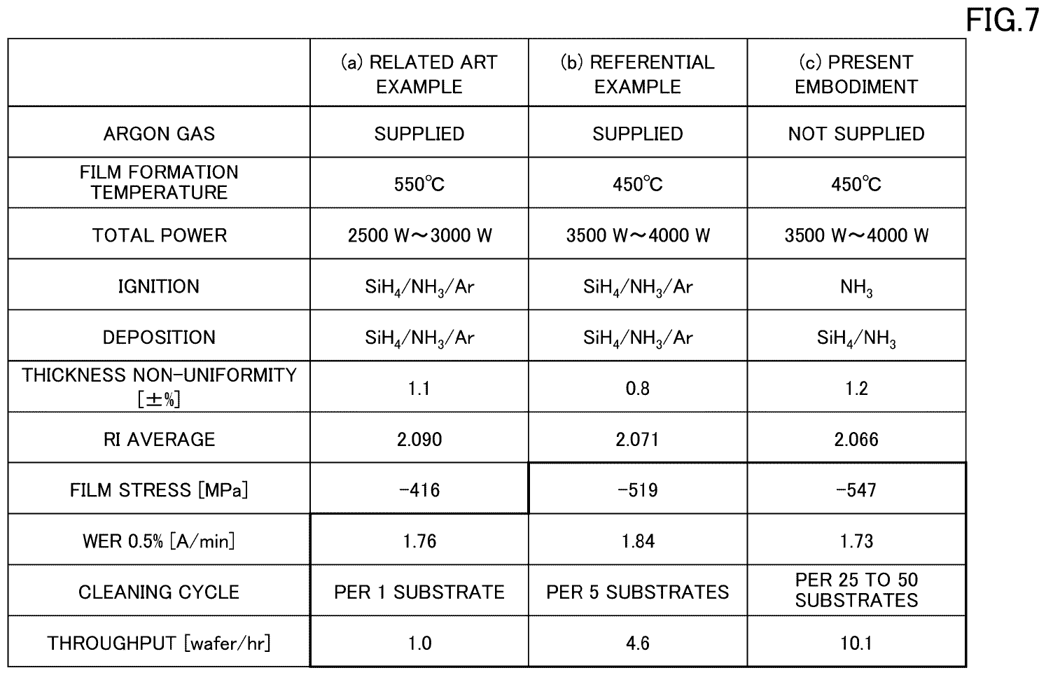

An example of the effect of the film formation process according to one embodiment will be described with reference to FIG. 7. In the above-described processing conditions of “(a) Related art example,” a gas including an argon gas, i.e., an SiH₄ gas, an NH₃ gas, and an Ar gas presented in “Ignition” in FIG. 7, was used as an ignition gas, the set temperature of the stage 11 was set to 550° C., and the total power was regulated to the range of 2,500 W to 3,000 W, and an SiN film is formed. In the processing conditions of “(b) Referential example,” a gas including an argon gas, i.e., an SiH₄ gas, an NH₃ gas, and an Ar gas, was used as an ignition gas, the set temperature of the stage 11 was set to 450° C., the total power was regulated to the range of 3,500 W to 4,000 W, and an SiN film was formed. Moreover, in the processing conditions of “(c) Present embodiment,” an argon gas was not used as an ignition gas, only an ammonia gas was used, the set temperature of the stage 11 was set to 450° C., the total power was regulated to the range of 3,500 W to 4,000 W, and an SiN film was formed. The total power is a total power of microwaves applied from the seven microwave radiation sources 42.

As a result, the uniformity of film thickness (Thickness Non-Uniformity) was approximately 1 in all of the examples and present embodiment, the uniformity of the film thickness was comparable, and the film thickness was uniform in all SiN films.

The RI (average value) and the film stress indicate that the film quality changed when the values changed. The results of RI and the film stress were comparable values among the examples and present embodiment, and the same film quality as the film quality of “(a) Related art example” in which film formation was performed by setting the set temperature at 550° C. was achieved in the low temperature processes of “(b) Referential example” and “(c) Present embodiment.”

The results of WER demonstrated that the same etching resistance as the etching resistance of “(a) Related art example” in which film formation was performed by setting the set temperature at 550° C. was achieved in the low temperature processes of “(b) Referential example” and “(c) Present embodiment.”

The results of the cleaning cycle (CLN cycle) demonstrated that, in the case of “(c) Present embodiment,” the cleaning cycle was improved such that the film formation could be continuously performed on at least twenty-five substrates up to approximately fifty substrates. As a result, the throughput significantly improved to 10 times the throughput of “(a) Related art example.”

As described above, the SiN film formation method and plasma processing apparatus of the present embodiment can form an SiN film having excellent etching resistance at high productivity.

The SiN film formation method and plasma processing apparatus according to the present embodiment are merely examples in all respects and should not be construed as being limited thereto. The embodiments may be modified and improved in various forms without departing from the scope and spirit of the appended claims. The features described in the embodiments may be implemented through another configuration, or may be combined with one another, provided that no inconsistency is caused.

What is claimed is:

1. An SiN film formation method comprising:
a) loading a substrate into a processing chamber;
b) supplying a nitrogen-containing gas to the processing chamber;
c) after b), applying electromagnetic power to generate plasma of the nitrogen-containing gas in the processing chamber; and
d) after c), supplying a silicon-containing raw material gas to the processing chamber, and allowing the silicon-containing raw material gas to react with the plasma of the nitrogen-containing gas, thereby forming an SiN film on the substrate.

2. The SiN film formation method according to claim 1, further comprising:
e) after b) and before d), stabilizing the plasma.

3. The SiN film formation method according to claim 2,
wherein duration of e) is in a range of 1 second to 5 seconds.

4. The SiN film formation method according to claim 1,
wherein the processing chamber includes a first gas supply hole configured to supply a gas from a ceiling wall of the processing chamber, and a second gas supply hole configured to supply a gas from a side wall of the processing chamber, and
wherein the silicon-containing raw material gas is supplied from the first gas supply hole and the second gas supply hole.

5. The SiN film formation method according to claim 4,
wherein a ratio of a flow rate of the silicon-containing raw material gas supplied from the first gas supply hole to a flow rate of the silicon-containing raw material gas supplied from the second gas supply hole is in a range of 1:1 to 1:5.

6. The SiN film formation method according to claim 4,
wherein the silicon-containing raw material gas is supplied from the first gas supply hole, followed by being supplied from the second gas supply hole.

7. The SiN film formation method according to claim 4,
wherein the silicon-containing raw material gas is simultaneously supplied from the first gas supply hole and the second gas supply hole.

8. The SiN film formation method according to claim 1,
wherein the electromagnetic power is applied by multiple microwave radiation sources.

9. The SiN film formation method according to claim 8,
wherein d) includes adjusting a set temperature of a stage on which the substrate is placed to 450° C. or lower, and applying a total power of microwaves that is 1.3 times to 1.4 times a total power of microwaves applied by the multiple microwave radiation sources with the set temperature of 550° C.

10. The SiN film formation method according to claim 8, further comprising:
f) after forming the SiN film on a set number of the substrates, supplying a processing gas including a fluorine-containing gas to the processing chamber, applying microwave power from the multiple microwave radiation sources to generate plasma of the processing gas in the processing chamber, and exposing an interior of the processing chamber to the plasma of the processing gas to clean the interior of the processing chamber.

11. The SiN film formation method according to claim 10,
wherein the set number of the substrates is from 25 substrates to 50 substrates.

12. The SiN film formation method according to claim 10,
wherein a set temperature of a stage on which the substrate is placed at d) and a set temperature of the stage at f) are a same temperature.

13. The SiN film formation method according to claim 12,
wherein the set temperature is 450° C. or lower.

14. The SiN film formation method according to claim 10, further comprising:
g) after f), forming a protective film on the interior of the processing chamber.

15. The SiN film formation method according to claim 14,
wherein the protective film is an SiN film.

16. The SiN film formation method according to claim 14,
wherein g) is performed under same processing conditions as processing conditions of d).

17. A plasma processing apparatus comprising:
a processing chamber;
an electromagnetic wave source configured to apply electromagnetic power;
a gas source configured to supply a gas;
a program storage; and
a processor coupled to the program storage, and configured to perform a process including:
a) loading a substrate into the processing chamber;
b) supplying a nitrogen-containing gas to the processing chamber;
c) after b), applying electromagnetic power to generate plasma of the nitrogen-containing gas in the processing chamber; and
d) after c), supplying a silicon-containing raw material gas to the processing chamber, and allowing the silicon-containing raw material gas to react with the plasma of the nitrogen-containing gas, thereby forming an SiN film on the substrate.
